(19) United States
(12) Patent Application Publication
(10) Pub. No.: US 2022/0238799 A1
(43) Pub. Date: Jul. 28, 2022

(54) MAGNETORESISTIVE ELEMENT HAVING A COMPOSITE RECORDING STRUCTURE

(71) Applicants: Yimin Guo, San Jose, CA (US); Rongfu Xiao, Dublin, CA (US); Jun Chen, Fremont, CA (US)

(72) Inventors: Yimin Guo, San Jose, CA (US); Rongfu Xiao, Dublin, CA (US); Jun Chen, Fremont, CA (US)

(21) Appl. No.: 17/160,349

(22) Filed: Jan. 27, 2021

(51) Int. Cl. H01L 43/12; H01L 43/10; H01L 43/02

(52) U.S. Cl. CPC H01L 43/12; H01L 43/02; H01L 43/10

(57) ABSTRACT

A method of forming a bottom-pinned magnetoresistive element comprising a composite recording structure that includes a first magnetic free layer and a second magnetic free layer containing Ni atoms, separated by an oxide spacing layer. The first magnetic free layer is Ni-free and the first magnetic free layer and the second magnetic free layer are magnetically parallel-coupled. A magnetic STT-enhancing structure is further provided atop the cap layer, wherein the magnetic STT-enhancing structure comprises a first magnetic material layer atop the cap layer and having a perpendicular magnetic anisotropy and an invariable magnetization anti-parallel to the magnetization direction of the reference layer, a second anti-ferromagnetic coupling (AFC) layer atop the first magnetic material layer, and a second magnetic material layer atop the second AFC layer.

### BACKGROUND OF THE INVENTION

### 1. Field of the Invention

This invention relates to the field of magnetoresistive elements. More specifically, the invention comprises magnetic-random-access memory (MRAM) using magnetoresistive elements with composite recording structures having additional Ni-containing magnetic free layers for fast writing and low powers as basic memory cells which potentially replace the conventional semiconductor memory used in electronic chips, especially mobile chips for power saving and non-volatility as well as memory blocks in processor-in-memory (PIM).

### 2. Description of the Related Art

In recent years, magnetic random access memories (hereinafter referred to as MRAMs) using the magnetoresistive effect of ferromagnetic tunnel junctions (also called MTJs) have been drawing increasing attention as the next-generation solid-state nonvolatile memories that can cope with high-speed reading and writing, large capacities, and low-power-consumption operations. A ferromagnetic tunnel junction has a three-layer stack structure formed by stacking a recording layer having a changeable magnetization direction, an insulating spacing layer (also called a tunnel barrier layer), and a fixed reference layer that is located on the opposite side from the recording layer and maintains a predetermined magnetization direction. The change of electrical resistance of the MTJ device is attributed to the difference in the tunneling probability of the spin polarized electrons through the tunnel barrier on the bias voltage across the device in accordance with the relative orientation of magnetizations of the ferromagnetic recording layer and the ferromagnetic reference layer. The ferromagnetic recording layer is also referred to as a free layer. MR ratio is defined as (R_{AP}−R_{P})/R_{P}, where R_{AP} and R_{P} are resistances in anti-parallel and parallel magnetization at zero-magnetic field, respectively.

Further, as in a so-called perpendicular MTJ element, both two magnetization films of the recording layer and the reference layer have easy axes of magnetization in a direction perpendicular to the film plane due to their strong perpendicular magnetic anisotropies (PMA) induced by both interfacial interaction and/or crystalline structure (shape anisotropies are not used), and accordingly, the device size can be made smaller than that of an in-plane magnetization type. Also, the variance in the easy axis of magnetization can be made smaller. Accordingly, by using a material having a large perpendicular magnetic anisotropy, both miniaturization and lower currents can be expected to be achieved while a thermal disturbance resistance is maintained.

There has been a known technique for achieving a high MR ratio and a high PMA in an MTJ element by forming an underneath MgO tunnel barrier layer and an MgO cap layer that sandwich a recording layer having a pair of amorphous CoFeB ferromagnetic sub-layers, i.e., the first free sub-layer (FL1) and the second free sub-layer (FL2), and a Boron-absorbing sub-layer positioned between them, and performing a thermal annealing process to accelerate crystallization of the amorphous ferromagnetic film to match interfacial grain structure to both the MgO tunnel barrier layer and the MgO cap layer. An MgO layer has a rocksalt crystalline structure in which each of Mg and O atoms forms a separate face-centered cubic (FCC) lattice, and Mg and O atoms together form a simple cubic lattice. The Boron-absorbing sub-layer is typically made of Mo or W material. The recording layer crystallization starts from both the MgO tunnel barrier layer interface and the MgO cap layer interface to its center and forms a CoFe grain structure, which is mainly a body-centered cubic (bcc) crystalline structure, having a volume perpendicular magnetic anisotropy (vPMA), as Boron atoms migrate into the Boron-absorbing sub-layer. In the same time, a typical bcc-CoFe(100)/rocksalt-MgO(100) texture occurs at the interface between a CoFeB sub-layer and an MgO layer. At two MgO interfaces, the orbital hybridization between cobalt 3dz2 and oxygen 2p orbitals significantly lowers the energy of the Co—O bonds, which leads to an interfacial perpendicular magnetic anisotropy. This is the same for a CoFeB reference layer underneath the MgO tunnel barrier layer. Accordingly, a coherent perpendicular magnetic tunneling junction structure is formed as an unique structure: bcc-CoFe(reference-layer)/rocksalt-MgO/bcc-CoFe/(W-boride or Mo-boride)/bcc-CoFe/rocksalt-MgO after a thermal annealing process. By using this technique, both a high MR ratio and a high PMA can be readily achieved.

It is reported (see Article: Co/Ni Multilayers With Perpendicular Anisotropy For Spintronic Device Applications, APPLIED PHYSICS LETTERS 100, 172411, 2012, by You, et al.) that a strong perpendicular anisotropy can also be obtained in as-deposited and annealed Co/Ni multilayers grown on a Pt buffer layer. However, for a Co/Ni multilayer grown on an MgO buffer layer, a much less perpendicular anisotropy is achieved even after annealing at 250° C. for 30 min. More importantly, a Co/Ni multilayer has an FCC (111) crystalline structure that does not provide the same structure matching to rocksalt-MgO (100) employed in high-TMR MTJs with bcc-CoFe (100), which leads a low MR ratio. For these reasons, Co/Ni multilayers have only been used as a part of a reference structure or a recording structure below the tunnel barrier layer, such as disclosed in U.S. Pat. No. 8,987,847 by G. Jan, et al. and U.S. Patent Publication 2020/0243749A1 by D. Worledge, et al.

Magnetization direction of a free layer is used to store the data and can be switched by spin-polarized electrons (equivalently spin current) without a magnetic field. When the spin-polarized current flows through the free layer along a specific direction, the free layer absorbs spin angular momentum from the electrons and as a result, its magnetization direction is reversed when the magnitude of the current is sufficiently large. Furthermore, as the volume of the magnetic layer forming the free layer is smaller, the injected spin-polarized current to write or switch can be also smaller. Accordingly, this method is expected to be a write method that can achieve both device miniaturization and lower currents. However, for random-access-memory (RAM) like applications, this technology faces various challenges along with its merits, such as the reliability of a tunnel barrier, long write latency and small energy efficiency due to still high write current. In theory, the critical current with a sufficient long pulse needed to reverse the magnetization direction of the free layer is proportional to its damping constant and the energy barrier between R_{AP} and R_{P} states, and furthermore, the critical current rapidly increases with a shorter pulse. Roughly, the increased amount of the critical current is inversely proportional to the product of the damping constant and the effective PMA field (Hk) of the free layer. Since the PMA of the free layer needs to be sufficiently high to maintain a reasonable thermal stability factor (E/k_{B}T, where E is the product of the PMA and volume of the recording layer and also denotes the energy barrier between the two stable magnetization configurations of the recording layer, k_{B} is the Boltzmann constant, and T is the absolute temperature 300K) which is normally required to be larger than 70 in the operation temperature range, the current density for switching of perpendicular spin transfer torque MRAM (pSTT-MRAM) is relatively large and hence large transistors are inevitable to drive it, which thus significantly limits their future use for memory applications. Therefore, it is desired to develop new technologies to greatly reduce the critical current at a short pulse while keeping a high thermal stability factor.

### SUMMARY OF THE PRESENT INVENTION

In present invention, a perpendicular magnetoresistive element having a composite recording structure comprises: a reference layer having a magnetic anisotropy in a direction perpendicular to a film surface and having an invariable magnetization direction; a tunnel barrier layer provided on the reference layer; a composite recording structure provided on the tunnel barrier layer and having a first free layer (FL1), a second free layer (FL2) and a nonmagnetic spacing layer positioned between them, wherein the first free layer is a Ni-absent magnetic layer having a magnetic anisotropy in a direction perpendicular to a film surface and having a variable magnetization direction, and the second free layer is a Ni-containing magnetic layer having magnetic anisotropy in a direction perpendicular to a film surface and having a variable magnetization direction; a cap layer on the composite recording structure. Both the first magnetic free layer and the second magnetic free layer have high spin polarization degrees, and their magnetizations are ferromagnetically parallel-coupled across the nonmagnetic spacing layer but individually switchable by sufficiently large spin transfer torques. Preferably, the tunnel barrier layer and the nonmagnetic spacing layer are made of a rocksalt crystal oxide such as MgO, the FL1 is made of amorphous CoFeB or CoFeB/W (or Mo)/CoFeB. During a thermal annealing process, as the amorphous CoFeB material in the FL1 starts to crystallize to form body-centered cubic (bcc) CoFe grains, both the two interfaces of the FL1 with its underneath tunnel barrier layer and its top nonmagnetic spacing layer form bcc-CoFe/rocksalt-crystal and rocksalt-crystal/bcc-CoFe interface textures, respectively, and achieve an excellent TMR property and a strong perpendicular magnetic anisotropy. Here and thereafter throughout this application, each element written in the left side of “/” is stacked above an element written in the right side thereof.

According to one embodiment of the present disclosure, the FL2 is made of amorphous material comprising Ni, Co and B elements, and the cap layer is an oxide layer. During a thermal annealing process, like the FL1, the FL2 of amorphous material containing at least Ni, Co and B elements starts to crystallize to form grains and produces a strong perpendicular magnetic anisotropy from its interface with the oxide cap layer due to orbital hybridization. Since the FL2 contains Ni atoms, it has a sufficient high damping constant for a fast STT-driven magnetization reversal.

According to a second embodiment of the present disclosure, the FL2 is made of Co/Ni superlattice, and the cap layer is a metal layer having a FCC crystal structure such as NiCr or a HCP crystal structure such as Ru. After a thermal annealing process, a multilayered structure [Co/Ni]n, where n is a small positive integer, forms a better Co/Ni superlattice for a strong perpendicular magnetic anisotropy. Since the FL2 contains Ni atoms, it has a sufficient high damping constant for a fast STT-driven magnetization reversal. A third embodiment of the present disclosure is similar to the second embodiment except that an insertion layer provided between the nonmagnetic spacing layer and the FL2 of Co/Ni superlattice. The insertion layer is a thin metal layer which can grow more uniformly on the oxide surface than Co such that a smoother Co/Ni superlattice can be obtained and a high perpendicular magnetic anisotropy can be achieved. The insertion layer is preferred to contain Mo, Mg, Ti, V, Cr, Fe, Zr, Nb or Ru. Also in this invention, a substrate cooling process is applied during the FL2 deposition. A low temperature at the substrate is expected to reduce the mobility of arriving metal atom particles so that the metal island formation of the FL2 on the nonmagnetic spacing layer of oxide is suppressed.

In this invention, there is further a magnetic STT-enhancing structure provided on the cap layer as another embodiment of the invention. The magnetic STT-enhancing structure comprises: a first magnetic material layer atop the cap layer and having a magnetization direction antiparallel to the magnetization direction of the reference layer, an anti-ferromagnetic coupling (AFC) layer atop the first magnetic material layer and a second magnetic material layer atop the AFC and having a magnetization direction antiparallel to the magnetization direction of the first magnetic material layer. The cap layer is made of a nonmagnetic material having a large spin diffusion length such that the magnetic STT-enhancing structure introduces an additional spin transfer torque assisting the magnetization reversal of the recording layer during a write process.

The present invention comprises methods of manufacturing such perpendicular magnetoresistive elements for perpendicular STT-MRAM devices with high write speeds and low write currents while maintaining high thermal stabilities. The perpendicular magnetoresistive element in the invention is sandwiched between an upper electrode and a lower electrode of each MRAM memory cell, which also comprises a write circuit which bi-directionally supplies a spin polarized current to the magnetoresistive element and a select transistor electrically connected between the magnetoresistive element and the write circuit.

### BRIEF DESCRIPTION OF THE DRAWINGS

FIG. 1 is a cross-sectional view showing a schematic configuration of an MTJ element 1 as a first prior art.

FIG. 2 is a cross-sectional view showing a schematic configuration of an MTJ element 2, as a second prior art.

FIG. 3 is a cross-sectional view showing a schematic configuration of a recording structure having a first magnetic free layer, a nonmagnetic spacing layer and a second magnetic free layer which contains Ni atoms.

FIG. 4 is a cross-sectional view showing a schematic configuration of a recording structure having a first magnetic free layer, a nonmagnetic spacing layer and a second magnetic free layer of Co/Ni lattice.

FIG. 5 is a cross-sectional view showing a schematic configuration of a recording structure having a first magnetic free layer, a nonmagnetic spacing layer, an insertion layer and a second magnetic free layer of Co/Ni superlattice.

FIG. 6 is a cross-sectional view showing a schematic configuration of a recording structure having a first magnetic free layer, a nonmagnetic spacing layer, a second magnetic free layer which contains Ni atoms, a cap layer and a magnetic STT-enhancing structure.

### DETAILED DESCRIPTION OF THE INVENTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present. Here, and thereafter throughout this application, each element written in the left side of “/” is stacked above an element written in the right side thereof.

In general, according to one embodiment, there is provided a magnetoresistive element comprising:

a reference layer having a perpendicular magnetic anisotropy and having an invariable magnetization direction;

a tunnel barrier layer atop the reference layer;

a composite recording structure atop the tunnel barrier layer, and comprising: a first free layer (FL1), which contains no Ni atoms, atop the tunnel barrier layer and having a perpendicular magnetic anisotropy and a variable magnetization direction; a nonmagnetic spacing layer atop the first free layer; and a second free layer (FL2), which contains Ni atoms, atop the nonmagnetic spacing layer and having a perpendicular magnetic anisotropy and a variable magnetization direction, wherein the first free layer and the second free layer are magnetically parallel-coupled;

an optional insertion layer provided between the nonmagnetic spacing layer and the second free layer;

a cap layer atop the composite recording structure; and

an upper-contact multilayer provided on the most top of above said layers.

In another embodiment, there is provided a magnetoresistive element comprising:

a reference layer having a perpendicular magnetic anisotropy and having an invariable magnetization direction;

a tunnel barrier layer atop the reference layer;

a composite recording structure atop the tunnel barrier layer, and comprising: a first free layer (FL1), which contains no Ni atoms, atop the tunnel barrier layer and having a perpendicular magnetic anisotropy and a variable magnetization direction; a nonmagnetic spacing layer atop the first free layer; and a second free layer (FL2) which contains Ni atoms atop the nonmagnetic spacing layer and having a perpendicular magnetic anisotropy and a variable magnetization direction, wherein the first free layer and the second free layer are magnetically parallel-coupled;

an optional insertion layer provided between the nonmagnetic spacing layer and the second free layer;

a cap layer atop the composite recording structure;

an optional magnetic STT-enhancing structure atop the cap layer and comprising: a first perpendicular magnetic layer atop the cap layer and having a magnetization direction antiparallel to the magnetization direction of the reference layer, an AFC layer atop the first perpendicular magnetic layer and a second perpendicular magnetic layer atop the AFC and having a magnetization direction parallel to the magnetization direction of the reference layer; and

an upper-contact multilayer provided on the most top of above said layers.

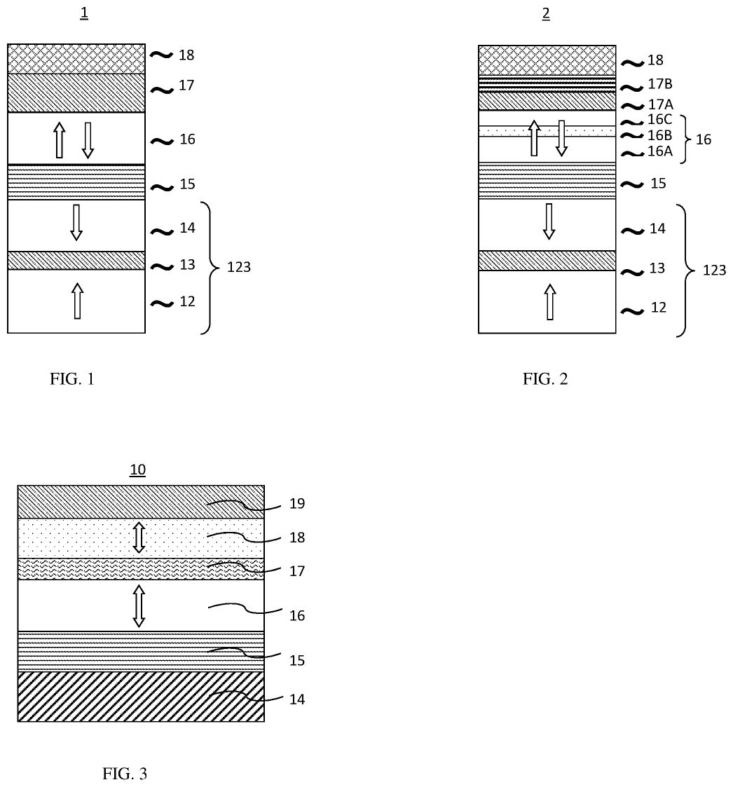

FIG. 1 is a cross-sectional view showing a configuration of an MTJ element 1 as a prior art. The MTJ element 1 is configured by stacking a bottom pinning layer 12, an anti-ferromagnetic coupling (AFC) layer 13, a reference layer 14, a tunnel barrier layer 15, a recording layer 16, a cap layer 17, and a protective layer 18 in this order from the bottom to the top. The bottom pinning layer 12 is typically made of super-lattice multilayer and has a strong perpendicular magnetic anisotropy. The bottom pinning layer 12 and the reference layer 14 are magnetically antiparallel-coupled through the anti-ferromagnetic coupling (AFC) layer 13, forming a reference structure 123. The tunnel barrier layer 15 is made of a non-magnetic insulating metal oxide or nitride. The recording layer 16 is made of ferromagnetic materials and has a magnetic anisotropy in a direction perpendicular to the film surface. The tri-layered structure consisting of the layers 14, 15 and 16 forms a magnetic tunneling junction (MTJ). The recording layer 16 has a variable (reversible) magnetization direction, while the reference layer 14 has an invariable (fixed) magnetization direction. The perpendicular magnetic anisotropic energy of the reference layer 14, partly coming from the antiparallel-coupling with the bottom pinning layer 12, is sufficiently greater than that of the recording layer 16. This strong perpendicular magnetic anisotropy can be achieved by selecting a material, configuration and a film thickness. The perpendicular resistance of the MTJ is high when the magnetizations between the recording layer 16 and the reference layer 14 are anti-parallel; and the perpendicular resistance of the MTJ is low when the magnetizations between the recording layer 16 and the reference layer 14 are parallel. Also in this manner, a spin polarized current may only reverse the magnetization direction of the recording layer 16 while the magnetization direction of the reference layer 14 remains unchanged. The cap layer 17 is a metal oxide layer and serves to introduce an interfacial perpendicular magnetic anisotropy for the recording layer 16. As an amorphous ferromagnetic material, CoFeB, in the recording layer is thermally annealed, a crystallization process occurs to form bcc CoFe grains having epitaxial growth with (100) plane parallel to surface of the tunnel barrier layer. The (100) texture extends across the whole stack from the tunnel barrier layer to the cap layer, producing a desired perpendicular magnetic anisotropy for the recording layer.

FIG. 2 is a cross-sectional view showing a configuration of an MTJ element 2 as a second prior art which is improved version of the first prior art. The MTJ element 2 is configured by stacking a bottom pinning layer 12, an anti-ferromagnetic coupling (AFC) layer 13, a reference layer 14, a tunnel barrier layer 15, a recording layer 16, a composite cap layer (17A & 17B), and a protective layer 18 in this order from the bottom to the top. The bottom pinning layer 12 is typically made of super-lattice multilayer and has a strong perpendicular magnetic anisotropy. The bottom pinning layer 12 and the reference layer 14 are magnetically antiparallel-coupled through the anti-ferromagnetic coupling (AFC) layer 13, forming a reference structure 123. The tunnel barrier layer 15 is made of a non-magnetic insulating metal oxide or nitride. The recording layer 16 has a magnetic anisotropy in a direction perpendicular to the film surface and consists of a first magnetic sub-layer 16A, a boron-absorbing sub-layer 16B and a second magnetic sub-layer 16C. The recording layer 16 has a variable (reversible) magnetization direction, while the reference layer 14 has an invariable (fixed) magnetization direction. When the MTJ stack is thermally annealed, a crystallization process of the amorphous ferromagnetic material, CoFeB, in the recording layer occurs to form bcc CoFe grains having epitaxial growth with (100) plane parallel to surface of the tunnel barrier layer and a volume perpendicular magnetic anisotropy is induced in the recording layer, as Boron atoms migrate towards boron-absorbing sub-layer in the middle of the recording layer. The first cap layer 17A is a metal oxide layer and the second cap layer 17B is an FCC-phased transition metal layer, forming a composite cap layer 18. The composite cap layer serves to introduce an enhanced interfacial perpendicular magnetic anisotropy for the recording layer.

### First Embodiment of Current Invention

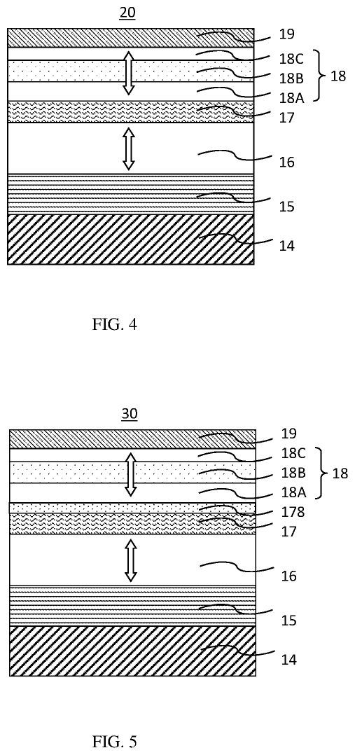

FIG. 3 is a cross-sectional view showing a configuration of an MTJ element 10 as deposited according to the first embodiment in this invention. The MTJ element 10 is configured by stacking a reference structure 14, a tunnel barrier layer 15, a composite recording structure comprising a first free layer (FL1) 16, a nonmagnetic spacing layer 17 and a second free layer (FL2) 18 and a cap layer 19 in the order from the bottom to the top.

The FL1 is made of a ferromagnetic material and FL2 is made of a Ni-containing ferromagnetic material. Magnetizations of FL1 (16) and FL2 (18) are parallel-coupled across the nonmagnetic spacing layer 17. Both of the FL1 and FL2 have perpendicular magnetic anisotropies and variable (reversible) magnetization directions. The reference structure has an invariable (fixing) magnetization direction. The reference structure is a synthetic anti-ferromagnetic structure having a perpendicular magnetic anisotropic energy which is sufficiently greater than both of the FL1 and the FL2. In this manner, a spin polarized current may only reverse the magnetization direction of the FL1 and the FL2 while the magnetization direction of the reference structure remains unchanged.

For an example, both the tunnel barrier layer 15 and the nonmagnetic spacing layer 17 are made of MgO and FL1 is made of CoFeB/Mo(or W)/CoFeB. When a thermal annealing process is applied after the MTJ stack deposition, as Boron elements migrate to the middle Mo (or W) atoms to form Mo boride (or W boride), a crystallization process of the FL1 layer occurs to form body-centered cubic (bcc) CoFe grains having an epitaxial growth, especially a bcc-CoFe (100)/MgO (100) texture with an atomic arrangement of 4-fold symmetry occurs at the interface between the CoFeB FL1 and the MgO tunnel barrier layer. This crystal texture is essential for achieving a high MR ratio.

The FL2 layer 18 is a Ni-containing ferromagnetic layer which has a higher damping constant than the FL1. For an example, the FL2 layer can a single layer or multilayer, such as NiCoB, NiCoFeB, NiCo, NiCoFe, NiCoB/Mo/NiCoB, NiCoB/W/NiCoB, NiCoFeB/Mo/NiCoFeB and NiCoFeB/W/NiCoFeB, etc. Preferably, the FL2 has a face-centered cubic (FCC) (111) texture or a body-centered cubic (bcc) (110). The cap layer 19 can be made of a metal oxide, such as MgO. After a thermally annealing process, a re-crystallization process occurs for the MgO cap layer 19 to form MgO (111) by 3-fold symmetry and further a crystallization process occurs for the FL2 layer to form face-centered cubic (FCC) or body-centered cubic (bcc) Ni-containing grains having an epitaxial growth with (111) plane parallel to the film surface. As a result, an MgO (111)/bcc-(110) or an MgO (111)/fcc-(111) texture is formed at the interface between the FL2 layer and the MgO cap layer. This crystal texture is essential for achieving a high interfacial perpendicular magnetic anisotropy of the FL2 layer. Both the first free layer and the second free layer have high spin polarization degrees, and their magnetizations are ferromagnetically parallel-coupled across the nonmagnetic spacing layer but individually switchable by sufficiently large spin transfer torques. As a result, the critical write current at a short pulse is reduced as one of the two free layers would switch first ahead of the other free layer, while the thermal stability factor of the parallel-coupled free layer structure is high.

An example configuration for the MTJ element 10 is described as follows. The reference structure 14 is made of CoFeB (around 1 nm)/W (around 0.2 nm)/Ru (around 0.5 nm)/Co (0.5 nm)/[Pt/Co]₃/Pt. The tunnel barrier layer 15 is made of MgO (around 1 nm). The first free layer 16 is made of CoFeB (around 0.6 nm)/Mo (0.3 nm)/CoFeB (around 1.55 nm). The nonmagnetic spacing layer 17 is made of MgO (around 0.7 nm). The second free layer 18 is made of NiCoB (around 1.0 nm)/W (0.2 nm)/NiCoB (around 1.0 nm). The cap layer 19 is made of MgO (around 0.8 nm).

### Second Embodiment of Current Invention

FIG. 4 is a cross-sectional view showing an example configuration of an MTJ element 20 as deposited according to the second embodiment. The MTJ element 20 is configured by stacking a reference structure 14, a tunnel barrier layer 15, a composite recording structure comprising a first free layer (FL1) 16, a nonmagnetic spacing layer 17, a second free layer (FL2) 18 having a super-lattice structure and a cap layer 19 in the order from the bottom to the top.

The FL1 is made of a ferromagnetic material and FL2 is made of a Ni-containing ferromagnetic material. Magnetizations of FL1 (16) and FL2 (18) are parallel-coupled across the nonmagnetic spacing layer 17. Both of the FL1 and FL2 have perpendicular magnetic anisotropies and variable (reversible) magnetization directions. The reference structure has an invariable (fixing) magnetization direction. The reference structure is a synthetic anti-ferromagnetic structure having a perpendicular magnetic anisotropic energy which is sufficiently greater than both of the FL1 and the FL2. In this manner, a spin polarized current may only reverse the magnetization direction of the FL1 and the FL2 while the magnetization direction of the reference structure remains unchanged.

For an example, both the tunnel barrier layer 15 and the nonmagnetic spacing layer 17 are made of MgO and the FL1 is made of CoFeB/Mo/CoFeB. When a thermal annealing process is applied after the MTJ stack deposition, as Boron elements migrate to the middle Mo atoms to form Mo boride, a crystallization process of the FL1 layer occurs to form body-centered cubic (bcc) CoFe grains having an epitaxial growth, especially a bcc-CoFe (100)/MgO (100) texture with an atomic arrangement of 4-fold symmetry occurs at the interface between the CoFeB FL1 and the MgO tunnel barrier layer. This crystal texture is essential for achieving a high MR ratio. In order to achieve a better growth of the FL2 with Co/Ni superlattices, the deposition of the nonmagnetic spacing layer of MgO may consists of at least two steps: first, forming an oxygen-rich MgO layer by using RF magnetron sputtering method, PECVD, CVD or Atomic Layer Deposition (ALD) method, and second, depositing a thin Mg layer on the oxygen-rich MgO layer by using DC magnetron sputtering method, PECVD, CVD or Atomic Layer Deposition (ALD) method. Doing so, the nonmagnetic spacing layer of MgO is Mg/MgO (O-rich) as deposited, and becomes stoichiometrically balanced MgO only after a thermal annealing process. Immediately after the deposition of the nonmagnetic spacing layer of Mg/MgO (O-rich), the FL2 with Co/Ni superlattices is deposited on the surface of the thin Mg layer, which leads to a better quality of Co/Ni superlattices.

The Co/Ni superlattice of FL2 layer gives rise to a higher damping constant and a higher perpendicular magnetic anisotropy than the FL1. For an example, the FL2 layer can be [Co/Ni]n, [Co/Ni]n/Co, [Co/Ni]n/CoFe, Ni/[Co/Ni]n, Ni/[Co/Ni]n/Co, or Ni/[Co/Ni]n/CoFe, where the repeating number n is a positive integer. Preferably, the first sub-layer of the FL2 super-lattice is deposited on a cold substrate in order to achieve a smoother layered structure. In order to make the FL2 have a better face-centered cubic (FCC) (111) texture, the cap layer 19 is preferred to be made of a transition metal or a transition metal alloy having a strong face-centered cubic (FCC) crystal structure or a hexagonal close-packed (HCP) crystal structure. The cap layer 19 can also be made of amorphous metal or thin metal oxide. After a thermally annealing process, the face-centered cubic (FCC) (111) texture of the FL2 is further improved and its perpendicular magnetic anisotropy is greatly enhanced. The thicknesses of Co and Ni in the FL2 super-lattice is arranged such that the FL2 has a high spin polarization degree, preferably above 80%. To achieve a high spin polarization degree, each Co sub-layer is about 2 ML (monolayer) thick. The PMA in Co/Ni super-lattice is closely linked to the Co/Ni interface and the effective perpendicular magnetic anisotropy can be tuned by controlling the Ni or Co thickness. In order to improve the smoothness of the FL2, a surface treatment such as sputter-etching may be conducted after the first sub-layer of the FL2 is deposited. Similar to the first embodiment, by adjusting the thickness of the nonmagnetic spacing layer, the magnetizations of the FL1 and the FL2 are ferromagnetically parallel-coupled across the nonmagnetic spacing layer but individually switchable by sufficiently large spin transfer torques. As a result, when the critical write current at a short pulse is applied along a specific direction, one of the two free layers would switch first ahead of the other free layer, while the thermal stability factor of the composite recording structure having parallel-coupled free layers is much higher than a single free layer.

An example configuration for the MTJ element 20 is described as follows. The reference structure 14 is made of CoFeB (around 1 nm)/W (around 0.2 nm)/Co (0.5 nm)/Ir (0.4-0.6 nm)/Co (0.5 nm)/[Pt/Co]₃/Pt. The tunnel barrier layer 15 is made of MgO (around 1 nm). The first free layer 16 is made of CoFeB (around 0.6 nm)/Mo (0.3 nm)/CoFeB (around 1.55 nm). The nonmagnetic spacing layer 17 is made of Mg (around 0.4 nm)/MgO (around 0.6 nm) or NiO (around 1.0 nm). The second free layer 18 is made of Co (0.4 nm)/[Ni (0.6 nm)/Co (0.4 nm)]₃. The cap layer 19 is made of NiCr (around 2.0 nm).

### Third Embodiment of Current Invention

FIG. 5 is a cross-sectional view showing a configuration of an MTJ element 30 as deposited according to the third embodiment. The MTJ element 30 is configured by stacking a reference structure 14, a tunnel barrier layer 15, a recording structure 16 comprising a first free layer (FL1) 16, a nonmagnetic spacing layer 17, an insertion layer 178, a second free layer (FL2) 18 having a super-lattice structure and a cap layer 19 in the order from the bottom to the top.

The FL1 is made of a ferromagnetic material and FL2 is made of a Ni-containing ferromagnetic material. Magnetizations of FL1 and FL2 are parallel-coupled across the nonmagnetic spacing layer 17. Both of the FL1 and FL2 have perpendicular magnetic anisotropies and variable (reversible) magnetization directions. The reference structure has an invariable (fixing) magnetization direction. The reference structure is a synthetic anti-ferromagnetic structure having a perpendicular magnetic anisotropic energy which is sufficiently greater than both of the FL1 and the FL2. In this manner, a spin polarized current may only reverse the magnetization direction of the FL1 and the FL2 while the magnetization direction of the reference structure remains unchanged.

For an example, both the tunnel barrier layer 15 and the nonmagnetic spacing layer 17 are made of MgO and FL1 is made of CoFeB/Mo (or W)/CoFeB. When a thermal annealing process is applied after the MTJ stack deposition, as Boron elements migrate to the middle Mo (or W) atoms to form Mo boride (or W boride), a crystallization process of the FL1 layer occurs to form body-centered cubic (bcc) CoFe grains having an epitaxial growth, especially a bcc-CoFe (100)/MgO (100) texture with an atomic arrangement of 4-fold symmetry occurs at the interface between the CoFeB FL1 and the MgO tunnel barrier layer. This crystal texture is essential for achieving a high MR ratio.

As the FL2 is deposited on an oxide surface, point defects, presumably oxygen vacancies, are traditionally considered preferential nucleation centers for FL2 metal island formation, which prohibits the growth of a high quality superlattice and leads to a poor perpendicular magnetic anisotropy if FL2 is made of Co/Ni superlattice. The insertion layer is a thin metal layer which can grow more uniformly on the oxide surface than Co. The insertion layer is preferred to contain Mo, Mg, Ti, V, Cr, Fe, Zr, Nb, Al or Ru. The FL2 layer 18 has a ferromagnetic super-lattice structure which has a higher damping constant and a higher perpendicular magnetic anisotropy than the FL1. For an example, the FL2 layer can be [Co/Ni]n, [Co/Ni]n/Co, [Co/Ni]n/CoFe, Ni/[Co/Ni]n, Ni/[Co/Ni]n/Co, or Ni/[Co/Ni]n/CoFe, where n is a positive integer. Preferably, the first sub-layer of the FL2 super-lattice is deposited on a cold substrate in order to achieve a smoother layered structure. The FL2 has a face-centered cubic (FCC) (111) texture. The cap layer 19 can be made of transition metal or transition metal alloy having a face-centered cubic (FCC) crystal structure or a hexagonal close-packed (HCP) crystal structure. The cap layer 19 can also be made of amorphous metal or thin metal oxide. After a thermally annealing process, the face-centered cubic (FCC) (111) texture of the FL2 is further improved and its perpendicular magnetic anisotropy is greatly enhanced. The thicknesses of Co and Ni in the FL2 super-lattice is arranged such that the FL2 has a high spin polarization degree above 80%. To achieve a high spin polarization degree, each Co is about 2 ML (monolayer) thick. The PMA in Co/Ni super-lattice is closely linked to the Co/Ni interface and the effective perpendicular magnetic anisotropy can be tuned by controlling the Ni or Co thickness. In order to improve the smoothness of the FL2, a surface treatment such as sputter-etching may be conducted after the first sub-layer is deposited.

An example configuration for the MTJ element 20 is described as follows. The reference structure 14 is made of CoFeB (around 1 nm)/W (around 0.2 nm)/Co (0.5 nm)/Ir (around 0.4-0.6 nm)/Co (0.5 nm)/[Pt/Co]3/Pt. The tunnel barrier layer 15 is made of MgO (around 1 nm). The first free layer 16 is made of CoFeB (around 0.6 nm)/Mo (0.3 nm)/CoFeB (around 1.55 nm). The nonmagnetic spacing layer 17 is made of MgO (around 0.7 nm) or NiO (around 1.0 nm). The insertion layer is made of FeMo or Ru (about 0.2 nm). The second free layer 18 is made of Ni (0.2 nm)/Co (0.4 nm)/[Ni (0.6 nm)/Co (0.4 nm)]₂/Ni (0.4 nm). The cap layer 19 is made of NiCr (around 2.0 nm).

### Fourth Embodiment of Current Invention

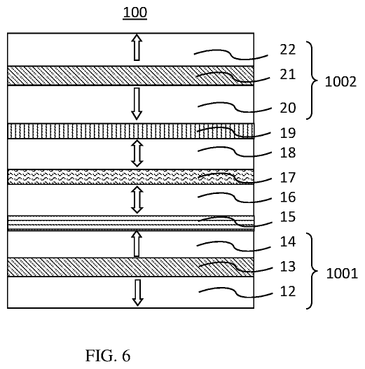

FIG. 6 is a cross-sectional view showing a configuration of an MTJ element 100 as deposited according to the first embodiment in this invention. The MTJ element 100 is configured by stacking a reference structure 1001, a tunnel barrier layer 15, a recording structure 16 comprising a first free layer (FL1) 16, a nonmagnetic spacing layer 17 and a second free layer (FL2) 18, a cap layer 19 and a magnetic STT-enhancing structure 1002 in the order from the bottom to the top.

The reference structure 1001 comprises a bottom pinning layer 12, an anti-ferromagnetic coupling (AFC) layer 13 and a reference layer 14. The bottom pinning layer 12 is typically made of super-lattice multilayer and has a strong perpendicular magnetic anisotropy. The bottom pinning layer 12 and the reference layer 14 are magnetically antiparallel-coupled through the anti-ferromagnetic coupling (AFC) layer 13. FL1 is made of a ferromagnetic material and FL2 is made of a Ni-containing ferromagnetic material. Magnetizations of FL1 and FL2 are parallel-coupled across the nonmagnetic spacing layer 17. Both of the FL1 and FL2 have perpendicular magnetic anisotropies and variable (reversible) magnetization directions. The reference structure has an invariable (fixing) magnetization direction. The reference structure is a synthetic anti-ferromagnetic structure having a perpendicular magnetic anisotropic energy which is sufficiently greater than both of the FL1 and the FL2. In this manner, a spin polarized current may only reverse the magnetization direction of the FL1 and the FL2 while the magnetization direction of the reference structure remains unchanged.

For an example, both the tunnel barrier layer 15 and the nonmagnetic spacing layer 17 are made of MgO and FL1 is made of CoFeB/Mo (or W)/CoFeB. When a thermal annealing process is applied after the MTJ stack deposition, as Boron elements migrate to the middle Mo (or W) atoms to form Mo boride (or W boride), a crystallization process of the FL1 layer occurs to form body-centered cubic (bcc) CoFe grains having an epitaxial growth, especially a bcc-CoFe (100)/MgO (100) texture with an atomic arrangement of 4-fold symmetry occurs at the interface between the CoFeB FL1 and the MgO tunnel barrier layer. This crystal texture is essential for achieving a high MR ratio.

The FL2 layer 18 is a Ni-containing ferromagnetic layer which has a higher damping constant than the FL1. For an example, the FL2 layer can a single layer or multilayer of NiCoB, or NiCoFeB, NiCo, NiCoFe, NiCoB/Mo/NiCoB and NiCoFeB/Mo/NiCoFeB, etc. Preferably, the FL2 has a face-centered cubic (FCC) (111) texture or a body-centered cubic (bcc) (110). The cap layer 19 can be made of a metal oxide, such as MgO. After a thermally annealing process, a re-crystallization process occurs for the MgO cap layer 19 to form MgO (111) by 3-fold symmetry and further a crystallization process occurs for the FL2 layer to form face-centered cubic (FCC) or body-centered cubic (bcc) Ni-containing grains having an epitaxial growth with (111) plane parallel to the film surface. As a result, an MgO (111)/bcc-(110) or an MgO (111)/fcc-(111) texture is formed at the interface between the FL2 layer and the MgO cap layer. This crystal texture is essential for achieving a giant interfacial perpendicular magnetic anisotropy of the FL2 layer. The FL2 layer can also be [Co/Ni]n, [Co/Ni]n/Co, [Co/Ni]n/CoFe, Ni/[Co/Ni]n, Ni/[Co/Ni]n/Co, or Ni/[Co/Ni]n/CoFe, where n is a positive integer. Preferably, the first sub-layer of the FL2 super-lattice is deposited on a cold substrate in order to achieve a smoother layered structure. The FL2 has a face-centered cubic (FCC) (111) texture.

The magnetic STT-enhancing structure 1002 comprises a first magnetic material layer 20 having a magnetization direction parallel to the magnetization direction of the reference layer, a second AFC coupling layer 21 and a second magnetic material layer 22. The first magnetic material layer 20 has a high spin polarization degree. The second magnetic material layer 22 is typically made of super-lattice multilayer and has a strong perpendicular magnetic anisotropy. The first magnetic material layer 20 and the second magnetic material layer 22 are magnetically antiparallel-coupled through the anti-ferromagnetic coupling (AFC) layer 21. The cap layer between the FL2 and the magnetic STT-enhancing structure 1002 is a nonmagnetic layer having a sufficient large spin diffusion length so that a spin polarized current is able to flow across the cap layer without significant degradation of the spin current polarization.

An example configuration for the MTJ element 100 is described as follows. The reference structure 1001 is made of CoFeB (around 1 nm)/W (around 0.2 nm)/Co (0.5 nm)/Ir (0.4-0.6 nm)/Co (0.5 nm)/[Pt/Co]₃/Pt. The tunnel barrier layer 15 is made of MgO (around 1 nm). The first free layer 16 is made of CoFeB (around 0.6 nm)/Mo (0.3 nm)/CoFeB (around 1.55 nm). The nonmagnetic spacing layer 17 is made of MgO (around 0.7 nm) or NiO (around 1.0 nm). The second free layer 18 is made of Ni (0.2 nm)/Co (0.4 nm)/Ni (0.6 nm)/Co (0.4 nm)/Ni (0.6). The cap layer 19 is made of Ru (around 2.0 nm). The magnetic STT-enhancing structure 1002 is made of Pt/[Co/Pt]₃/Co (0.5 nm)/Ir (around 0.4-0.6 nm)/Co (0.5 nm)/W (around 0.2 nm)/CoFeB (around 1 nm).

### Fifth Embodiment of Current Invention

As the MIT pillar size is getting smaller for future technology node and higher density, the thermal stability factor has to maintain the same. The composite recording structure comprises a first free layer (FL1), a first nonmagnetic spacing layer, a second free layer (FL2), a second nonmagnetic spacing layer, a third free layer (FL3) in the order from the bottom to the top (not shown here). The composite recording structure may have more free layers which are interleaved by nonmagnetic spacing layers. The magnetizations of the i-th free layer and (i+1)-th free layer are ferromagnetically parallel-coupled across the i-th nonmagnetic spacing layer, but individually switchable by sufficiently large spin transfer torques. Since the first free layer is crucial for a high MR-ratio, it is preferred to have amorphous CoFeB material which is capable to form a desired bcc-CoFe (100)/MgO (100) texture after thermal annealing. The second free layer and rest free layer above the second free layer could have Co/Ni superlattices which provide perpendicular magnetic anisotropies.

A cap layer is provided on the composite recording layer, and a magnetic STT-enhancing structure is provided on the cap layer. The magnetic STT-enhancing structure comprises a first magnetic material layer having a magnetization direction parallel to the magnetization direction of the reference layer and a second magnetic material layer separated a AFC coupling layer and. The first magnetic material layer has a high spin polarization degree. The second magnetic material layer is typically made of super-lattice multilayer and has a strong perpendicular magnetic anisotropy. The first magnetic material layer and the second magnetic material layer are magnetically antiparallel-coupled through the anti-ferromagnetic coupling (AFC) layer. The cap layer between the top free layer in the composite recording structure and the magnetic STT-enhancing structure is a nonmagnetic layer having a sufficient large spin diffusion length so that a spin polarized current is able to flow across the cap layer without significant degradation of the spin current polarization.

As an alternative, the magnetic STT-enhancing structure may comprise a half-metal material which has a high spin polarization degree such that a highly spin polarized current is able to flow across the cap layer into the composite recording structure for better spin transfer torques driven reversal of the magnetizations of the free layers.

While certain embodiments have been described above, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A method of manufacturing a magnetoresistive element for being used in a magnetic memory device comprising:
providing a substrate;
forming a bottom contact layer atop the substrate;
forming a reference structure atop the bottom contact layer and comprising a magnetic reference layer have a perpendicular magnetic anisotropy and invariable magnetization direction;
forming a tunnel barrier layer atop the reference structure;
forming a recording structure comprising: forming a first magnetic free layer atop the tunnel barrier layer; forming an oxide spacing layer atop the first magnetic free layer; and forming a second magnetic free layer atop the oxide spacing layer, wherein the first magnetic free layer contains no Nickel (Ni) elements, the second magnetic free layer comprises at least one Ni-alloy layer, and the first magnetic free layer and the second magnetic free layer are ferromagnetically-coupled across the oxide spacing layer; and
forming an oxide cap layer atop the recording structure,
wherein both the interface between the tunnel barrier layer and the first magnetic free layer and the interface between the oxide spacing layer and the first magnetic free layer provide perpendicular magnetic anisotropies for the first magnetic free layer, both the interface between the oxide spacing layer and the second magnetic free layer and the interface between the oxide cap layer and the second magnetic free layer provide perpendicular magnetic anisotropies for the second magnetic free layer.

2. The element of claim 1, wherein the tunnel barrier layer consists of one of MgO, MgZnO, MgZrO and MgAlO, the oxide spacing layer consists of one of MgO, ZnO, TiO, MgZnO, MgTiO, ZrO, MgZrO, MgAlO, TaO, Al₂O₃, NiO and SiO₂, and the oxide cap layer consists of one of MgO, ZnO, TiO, MgZnO, MgTiO, ZrO, MgZrO, MgAlO, TaO, Al₂O₃, NiO and SiO₂.

3. The element of claim 1, wherein the first magnetic free layer comprises at least one ferromagnetic Boron alloy layer selected from the group of CoFeB, CoB and FeB, the B composition percentage is between 10%-35%.

4. The element of claim 1, wherein the first magnetic free layer comprises a first magnetic sub-layer, preferred to be CoFeB, CoFeB/Fe, CoFe/CoFeB or CoFeB/CoFe, and a second magnetic sub-layer, preferred to be CoFeB or CoB, and a Boron-absorbing sub-layer provided between the first magnetic sub-layer and the second magnetic sub-layer and containing at least one element selected from the group of Ta, Hf, Zr, Ti, Mg, Nb, W, Mo, Ru, Al and having a thickness less than 0.4 nm.

5. The element of claim 1, wherein the second magnetic free layer comprises at least one ferromagnetic Boron alloy layer or multilayer selected from the group of NiB, NiCoB, NiCoFeB, NiFeB, NiCoB/M/NiB, NiCoB/M/NiFeB, NiCoB/M/NiCoB, NiCoB/M/NiCoFeB, NiCoFeB/M/NiB, NiCoFeB/M/NiCoB, NiCoFeB/M/NiCoFeB and NiCoFeB/M/NiFeB, the B composition percentage is between 5%-35%, wherein M is a metal sub-layer containing at least one element selected from the group of Ta, Hf, Zr, Ti, Mg, Nb, W, Mo, Ru, Al and having a thickness less than 0.4 nm.

6. The element of claim 1, the forming of said reference structure further comprising: forming a seed layer atop the bottom contact layer; forming a magnetic pinning layer atop the seed layer; forming a first anti-ferromagnetic coupling (AFC) layer atop the pinning layer; forming a magnetic reference layer atop the first AFC layer, wherein the magnetic pinning layer and the magnetic reference layer have perpendicular magnetic anisotropies and invariable magnetization directions, and are antiferromagnetically coupled through the first AFC layer.

7. The element of claim 1 further comprising forming a magnetic STT-enhancing structure atop the oxide cap layer, wherein the magnetic STT-enhancing structure comprises a first magnetic material layer atop the oxide cap layer and having a perpendicular magnetic anisotropy and an invariable magnetization anti-parallel to the magnetization direction of the magnetic reference layer, a second anti-ferromagnetic coupling (AFC) layer atop the first magnetic material layer, and a second magnetic material layer atop the second AFC layer and having a perpendicular magnetic anisotropy and an invariable magnetization in a direction perpendicular to a film surface.

8. A method of manufacturing a magnetoresistive element for being used in a magnetic memory device comprising:
providing a substrate;
forming a bottom contact layer atop the substrate;
forming a reference structure comprising: forming a seed layer atop the bottom contact layer; forming a magnetic pinning layer atop the seed layer; forming a first anti-ferromagnetic coupling (AFC) layer atop the pinning layer; forming a magnetic reference layer atop the first AFC layer, wherein the magnetic pinning layer and the magnetic reference layer have perpendicular magnetic anisotropies and invariable magnetization directions, and are antiferromagnetically coupled through the first AFC layer;
forming a tunnel barrier layer atop the magnetic reference layer;
forming a recording structure comprising: forming a first magnetic free layer atop the tunnel barrier layer; forming an oxide spacing layer atop the first magnetic free layer; and forming a second magnetic free layer atop the oxide spacing layer, wherein the first magnetic free layer contains no Nickel (Ni) elements, the second magnetic free layer comprises a Co/Ni superlattice, and the first magnetic free layer and the second magnetic free layer are ferromagnetically-coupled across the oxide spacing layer; and
forming a cap layer atop the recording structure,
wherein both the interface between the tunnel barrier layer and the first magnetic free layer and the interface between the oxide spacing layer and the first magnetic free layer provide perpendicular magnetic anisotropies for the first magnetic free layer, the second magnetic free layer has a perpendicular magnetic anisotropy.

9. The element of claim 8, wherein the tunnel barrier layer consists of one of MgO, MgZnO, MgZrO, MgTiO and MgAlO.

10. The element of claim 8, wherein forming the oxide spacing layer comprises forming a metal oxide layer comprising at least one metal element selected from the group of Mg, Zn, Ti, Zr, Al, Ta and Ni, and having a thickness between 0.6 nm and 2.0 nm.

11. The element of claim 10, wherein forming the metal oxide layer comprises:
(a) depositing a first metal layer by a DC magnetron sputtering process in a first chamber which is a sputter deposition chamber;
(b) performing a natural oxidation (NOX) process on the first metal layer in a second chamber which is an oxidation chamber to form a metal oxide layer thereon;
(c) depositing a second metal layer on said metal layer by a DC magnetron sputtering process in a sputter deposition chamber.

12. The element of claim 10, wherein forming the metal oxide layer comprises:
(a) depositing a first metal oxide layer by using RF magnetron sputtering method, PECVD, CVD or Atomic Layer Deposition (ALD) method;
(b) depositing a metal layer on the first metal oxide layer by using DC magnetron sputtering method, PECVD, CVD or Atomic Layer Deposition (ALD) method.

13. The element of claim 8, wherein the cap layer has a face-centered cubic (FCC) crystal structure, a hexagonal close-packed (HCP) crystal structure or an amorphous structure, preferred to be one selected from the group of NiFeCr, NiCr, Ru, NiRu, Cu, Pt, Ir, Ag, Au, NiCu, MgO, ZnO, TiO, MgZnO, MgTiO, ZrO, MgZrO, MgAlO, TaO, Al₂O₃ and SiO₂, and the cap layer has a thickness of at least 1 nm.

14. The element of claim 8, wherein the first magnetic free layer comprises at least one ferromagnetic Boron alloy layer selected from the group of CoFeB, CoB and FeB, the B composition percentage is between 10%-35%.

15. The element of claim 8, wherein the first magnetic free layer comprises a first magnetic sub-layer, preferred to be CoFeB, CoFeB/Fe, CoFe/CoFeB or CoFeB/CoFe, and a second magnetic sub-layer, preferred to be CoFeB or CoB, and a Boron-absorbing sub-layer provided between the first magnetic sub-layer and the second magnetic sub-layer and containing at least one element selected from the group of Ta, Hf, Zr, Ti, Mg, Nb, W, Mo, Ru, Al and having a thickness less than 0.4 nm.

16. The element of claim 8, wherein each Co sub-layer of the second magnetic free layer has a thickness between 0.3 nm and 0.5 nm, and the Ni sub-layer of the second magnetic free layer has a thickness between 0.2 nm and 0.7 nm, and the second magnetic free layer is preferred to be [Co/Ni]n, [Co/Ni]n/Co, [Co/Ni]n/CoFe, Ni/[Co/Ni]n, Ni/[Co/Ni]n/Co or Ni/[Co/Ni]n/CoFe, where n is a positive integer.

17. The element of claim 8 further comprising performing a substrate cooling between forming the tunnel barrier layer and forming the recording structure, and maintaining a cold substrate temperature during forming the recording structure.

18. The element of claim 8 further comprising forming an insertion layer between forming the oxide spacing layer and forming the second magnetic free layer, wherein the insertion layer is made of material being capable of smooth growth on the oxide surface, preferred to be Mo, Mg, Ti, V, Cr, Fe, Zr, Nb, Al or Ru, and the insertion layer has a thickness between 0.2 nm and 1.5 nm.

19. The element of claim 18 further comprising performing a surface treatment on the insertion layer immediately after forming an insertion layer, wherein the surface treatment includes sputter-etching or plasma bombardment.

20. The element of claim 8 further comprising forming a magnetic STT-enhancing structure atop the cap layer, wherein the magnetic STT-enhancing structure comprises a first magnetic material layer atop the cap layer and having a perpendicular magnetic anisotropy and an invariable magnetization anti-parallel to the magnetization direction of the reference layer, a second anti-ferromagnetic coupling (AFC) layer atop the first magnetic material layer, and a second magnetic material layer atop the second AFC layer and having a perpendicular magnetic anisotropy and an invariable magnetization in a direction perpendicular to a film surface.
